(19) United States
(12) Patent Application Publication
(10) Pub. No.: US 2025/0245209 A1
(43) Pub. Date: Jul. 31, 2025

(54) SYSTEM AND METHOD FOR COMPRESSING STORAGE SYSTEM MONITORING DATA

(71) Applicant: NetApp, Inc., San Jose, CA (US)

(72) Inventor: Carlos ROLO, Lisbon (PT)

(73) Assignee: NetApp, Inc., San Jose, CA (US)

(21) Appl. No.: 18/424,368

(22) Filed: Jan. 26, 2024

(51) Int. Cl. G06F 16/22; H03M 7/30

(52) U.S. Cl. CPC G06F 16/2228; H03M 7/6082

(57) ABSTRACT

Disclosed are methods and systems for processing storage system monitoring data. The time component may be removed from the storage system monitoring data and may be stored as a mathematical formula, such as a line. The data from the storage system monitoring data may be separately analyzed to determine a compression algorithm to be applied to the data, such that the compressed data may be stored as a mathematical formula. Storing the storage system monitoring data as a mathematical formula lowers the amount of storage needed to store the storage system monitoring data, lowers the amount of network bandwidth needed to transfer the storage system monitoring data, and lowers the processing resources needed to process the storage system monitoring data. The removed time component may be used as an index to access the compressed data.

### TECHNICAL FIELD

Embodiments of the present disclosure generally relate to efficiently storing data. More specifically, embodiments relate to systems and methods for efficiently compressing time series data, for example, monitoring data of storage systems.

### BACKGROUND

Storage system monitoring tools may be used to monitor various storage system metrics, such as central processing unit (CPU) utilization, storage utilization, database latency, disk latency, or other metrics. The storage system monitoring data may be stored and used for various purposes. The monitoring data may be collected and used in real-time to generate alerts relating to system failures, high latency situations, or other issues that may need immediate attention to resolve a problem. The collected monitoring data may also be used for generating customer reports (e.g., a customer may request a monthly report on storage utilization) and compliance (e.g., satisfying a regulatory compliance policy where a banking customer must store bank account records for 15 years).

Storage system monitoring data is often stored in a database so that query capabilities and correlation tools of the database can be used to process the data and generate reports. Over time, the collected storage system monitoring data can occupy a large amount of storage space and require large-size file transfers to transmit the data, either to another storage location (e.g., a cloud-based storage) or to a customer. Retaining all this data is a cost that companies have to incur with no real upside.

### SUMMARY

According to some embodiments of the present disclosure, there is provided a method for processing storage system monitoring data. The method includes splitting received storage system monitoring data into signal data and time information. The signal data can be pre-processed to perform a statistical analysis on the signal data. A compression algorithm can be selected based on the statistical analysis on the signal data. The signal data can be compressed using the selected compression algorithm. An index can be generated from the time information to access samples in the compressed data. The compressed data and the index can be output.

According to some embodiments of the present disclosure, there is provided a system. The system includes a memory configured to store instructions and a processor configured to execute the instructions stored in the memory that can cause the processor to split received storage system monitoring data into signal data and time information. The signal data can be pre-processed to perform a statistical analysis on the signal data. A compression algorithm can be selected based on the statistical analysis on the signal data. The signal data can be compressed using the selected compression algorithm. An index can be generated from the time information to access samples in the compressed data by determining a start time and an end time for a given interval and storing the start time, the end time, and the interval as a line. The compressed data and the index can be output.

According to some embodiments of the present disclosure, there is provided a non-transitory computer-readable medium containing instructions that, when executed by a machine, cause the machine to split received storage system monitoring data into signal data and time information. The signal data can be pre-processed to perform a statistical analysis on the signal data by dividing the signal data into segments, wherein each segment includes 2^{N} samples, where N is an integer, performing the statistical analysis on each segment. A compression algorithm can be selected for each segment based on the statistical analysis for each segment. The signal data of each segment can be compressed using the selected compression algorithm for each segment. An index can be generated from the time information to access samples in the compressed data. The compressed data and the index can be output.

### BRIEF DESCRIPTION OF THE DRAWINGS

FIG. 1A is an exemplary plot of data amount over time, consistent with some embodiments of the present disclosure.

FIG. 1B is an exemplary plot of data amount over time with a mathematical equation representing the data amount overlaid on the data plot shown in FIG. 1A, consistent with some embodiments of the present disclosure.

FIG. 2 is a system diagram of an exemplary storage system, consistent with some embodiments of the present disclosure.

FIG. 3A is a flow diagram showing an information flow for creating compressed data and an index from raw time series data, consistent with some embodiments of the present disclosure.

FIG. 3B is a flow diagram showing an alternate information flow for creating compressed data from raw time series data, consistent with some embodiments of the present disclosure.

FIGS. 4A-4D illustrate a flowchart of an exemplary method for creating compressed data and an index from time series data, consistent with some embodiments of the present disclosure.

FIG. 5 is a flow diagram showing an information flow for locating particular data in compressed time series data, consistent with some embodiments of the present disclosure.

FIG. 6 is a flowchart of an exemplary method for locating particular data in compressed time series data, consistent with some embodiments of the present disclosure.

FIG. 7 is a block diagram of an exemplary server that may be used in the system shown in FIG. 2, consistent with some embodiments of the present disclosure.

### DETAILED DESCRIPTION

Time series data is a collection of sampled data points, such as observations and measurements, at different time intervals over a period of time and ordered chronologically. For example, time series data may include weather observations for a particular location (e.g., temperature, humidity, and wind speed measured at different times during a day), stock market data (e.g., a price of a commodity at different times during a trading day), or health data (e.g., a heart rate monitored over a period of time). The frequency of time series data collection relates to the type of data being collected. For example, heart rate data may be collected every second, temperature data may be collected every five minutes, and stock market data may be collected every time a trade is made. As such, the time intervals between observations or measurements may be evenly spaced (heart rate data, temperature data) or may be unevenly spaced (stock market data). This relevance of time as an axis makes time series data distinct from other types of data.

Storage system monitoring data is an example of time series data. When a customer requests access to their storage system monitoring data (e.g., requests a view of historic CPU usage through a Web browser), network bandwidth and processing resources are consumed to present a particular view requested by the customer. As the volume of the monitoring data increases, presenting the monitoring data to the customer requires more storage space (at both the storage system provider's end and at the customer's end to receive the monitoring data), more network bandwidth to transmit the monitoring data, and more processing resources to prepare the monitoring data to be sent to the customer and to be processed for display to the customer once the data is received by the customer.

Storage system monitoring data may normally be characterized by a relatively low frequency sampling (e.g., 0.05 Hz to 1˜2 Hz) of processes. Other processes, such as database processes or operating system general health monitoring may generate a higher volume of signals. In most cases, the storage system monitoring data may not exhibit any periodicity or any harmonic components. As such, the monitoring data may be treated mostly as isolated samples or a short sequence of samples.

By processing the storage system monitoring data as one continuous signal, a series of techniques may be applied to reduce the storage requirements, and hence the transmission requirements for the data. Storage system monitoring data that is sent to external systems for storage and/or processing brings egress costs (i.e., the network bandwidth required to transfer the data between entities).

Reducing the storage and transmission requirements results in less storage space being needed, less data transmission bandwidth being needed to send the monitoring data to a customer, and fewer processing resources being needed to process the monitoring data.

The amount of storage system monitoring data that is available and retained requires large storage spaces and large amounts of network bandwidth to transfer the data. Some existing techniques, like averaging, may be used to drop data points within the monitoring data. For example, at the end of a day, an average of disk usage per hour may be stored instead of all the data points for that hour. As another example, at the end of a week, an average of the signals for each day of the week may be stored instead of all the data points for each day. However, while these techniques reduce the amount of information available, the granularity of the data points is lost by averaging the data points values and the original data point values may be lost.

Systems and methods consistent with the present disclosure relate generally to compressing and storing time series data, and more specifically, to methods, systems, and devices for removing the time component from the time series data, compressing and storing the data, and using the removed time component as an index into the compressed data. The present disclosure describes systems and methods to improve the efficiency of storing and managing storage system monitoring data such as CPU usage, memory usage, database latency, and disk latency data points in a manner that reduces the amount of storage space required to store the monitoring data without losing any relevant information.

For example, when monitoring storage system performance, a customer may only want to see historical usage trends, such that every individual data point of the monitoring data is not needed. As another example, the monitoring data may be used in real-time, to determine whether an immediate action needs to be taken (i.e., for real-time alerts). For example, if database latency suddenly increases over a high-level threshold, this may indicate that there is a database connectivity issue that needs to be quickly resolved. As another example, a customer may want to know, “what was my data usage over the last month?” to determine whether the customer needs more storage space on the storage system.

Consistent with some embodiments of the present disclosure, only a portion of the time series data may be retained. For example, if the time series data is storage system monitoring data, a customer's inquiry regarding occurrences from one year ago may be satisfied by using trends extracted from the retained data (i.e., every data point from the time period may not be needed to determine the trend). By not retaining every single data point, an error may be introduced without compromising the later use of the data. Instead of retaining every single data point, an approximation of the data series, with a small error margin (e.g., under 5%), may be provided. For example, similar data may be identified and only stored once, e.g., using delta compression or logical exclusive OR (XOR) compression for sequential data elements in the time series.

Along with a reduction in storage space, the present embodiments may also enable a reduction in network bandwidth and processing resources associated with providing customers access to compressed data. Instead of storing the raw storage system monitoring data, which can consume a large amount of storage, the storage system monitoring data may be transformed into a data format that can be easily and accurately represented by mathematical formulas. In some embodiments, the mathematical formulas may include, but are not limited to, a line (e.g., when the data is constant), a Fast Fourier Transform (FFT), a polynomial, or an audio file format. The mathematical formula consumes less storage space than the actual data points of the storage system monitoring data.

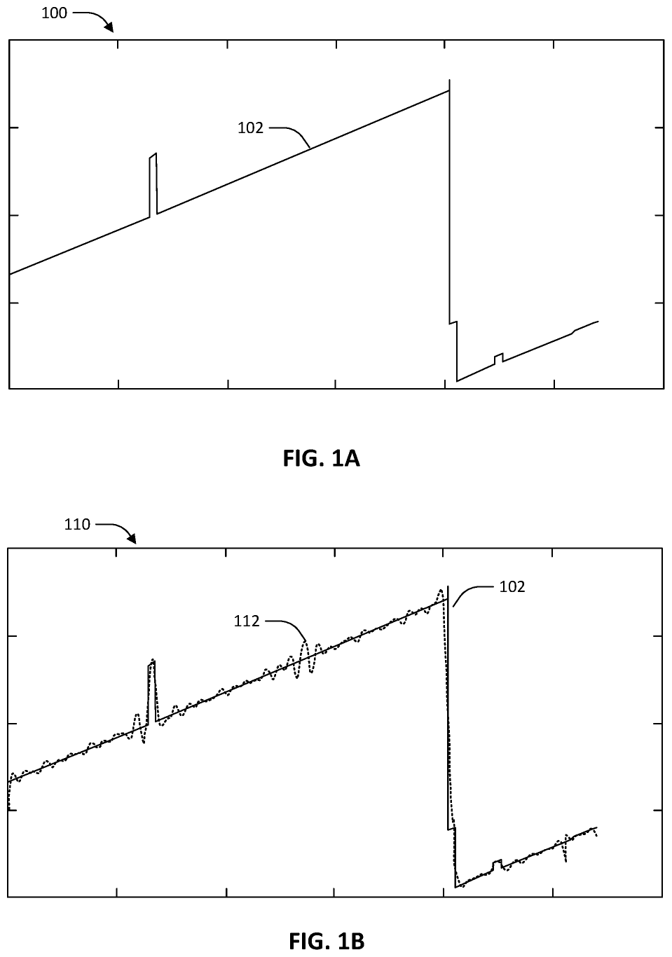

FIG. 1A is an exemplary plot 100 of an amount data accumulated over time, consistent with some embodiments of the present disclosure. As shown in FIG. 1A, the plot 100 includes a line 102 showing data amount (on the Y axis) accumulated over a period of time (shown on the X axis). The plot 100 is provided to illustrate an example of accumulated data over time, and the particular units of measurement for the data amount and the period of time may vary within the scope of the present disclosure. The line 102 shows a plurality of data points over the period of time. As described above, storing the data associated with each of the data points to enable the line 102 to be drawn requires a large amount of storage space.

FIG. 1B is an exemplary plot 110 of an amount data accumulated over time with a mathematical equation representing the data amount overlaid on the data plot, consistent with some embodiments of the present disclosure. As shown in FIG. 1B, the plot 110 includes the line 102 of data amount overlaid with a line 112 representing the mathematical equation that approximates the data amount used to construct line 102. Storing the mathematical formula used to draw line 112 requires less storage space than the amount of storage space required to store the data points required to draw line 102. The mathematical formula may represent a compression of the data accumulated over time.

By applying compression and processing techniques to time series data (e.g., storage system monitoring data) to represent the data as a mathematical formula, benefits such as reduced storage space and reduced network bandwidth required for data transmission may be achieved that were previously difficult to attain for conventionally stored time series data. For example, compressing and storing the time series data as a mathematical formula saves network bandwidth and processing resources by providing only the requested information.

The compression may be performed upon already stored data and/or for data to be transmitted (e.g., compression as part of transmitting time series data to cloud-based storage or computing). Also, while storage system monitoring data is used in this disclosure as an example of time series data, the systems and methods described herein are equally applicable to other types of time series data.

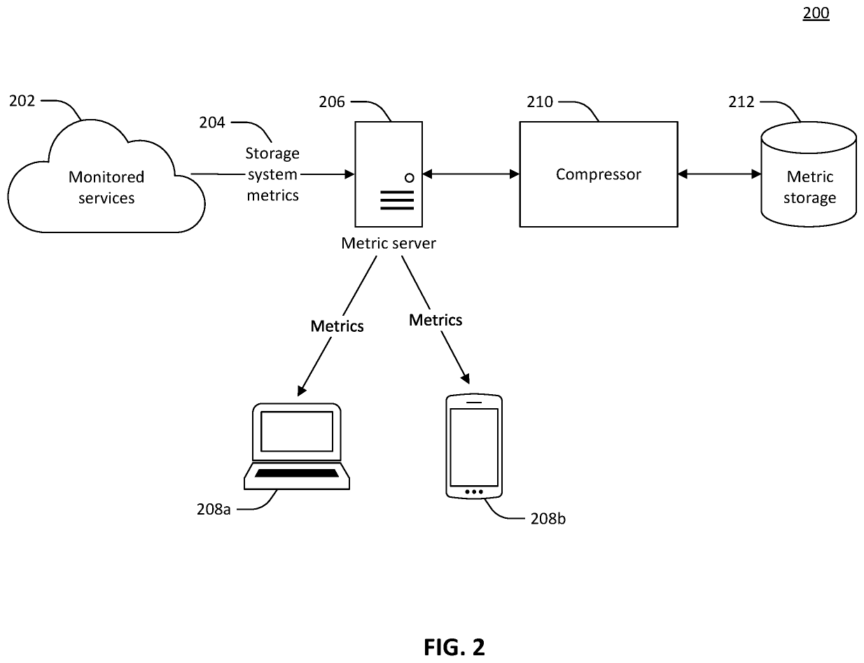

FIG. 2 is a system diagram of an exemplary storage system 200, consistent with some embodiments of the present disclosure. The storage system 200 may include a storage controller and one or more storage components, such as a disk shelf including a number of disk drives or a storage array (not shown in FIG. 2). These components provide a number of services that are monitored (e.g., monitored services 202) and generate storage system monitoring data (e.g., disk usage, CPU usage, memory usage, database latency, disk latency, and the like). In some embodiments, the monitored services 202 may be connected to a cloud computing environment.

The monitored services 202 generate storage system metrics 204 which are provided to a metric server 206. In some embodiments, the metrics 204 may be pushed from the monitored services 202 to the metric server 206. In other embodiments, the metrics 204 may be pulled by the metric server 206 from the monitored services 202.

The metric server 206 provides the metrics 204 to a compressor 210. In some embodiments, the metrics 204 may be pushed from the metric server 206 to the compressor 210. In other embodiments, the metrics 204 may be pulled by the compressor 210 from the metric server 206. As will be described below, the compressor 210 processes the metrics 204 by analyzing the metrics and compressing the metrics. The compressed metrics may be stored to and retrieved from a metric storage 212.

The metrics server 206 may provide metrics to various user devices 208a, 208b such that a user may view the metrics 204 in some form (e.g., raw metric data, summarized or compressed metric data, or metric data trends).

### Exemplary Write Path

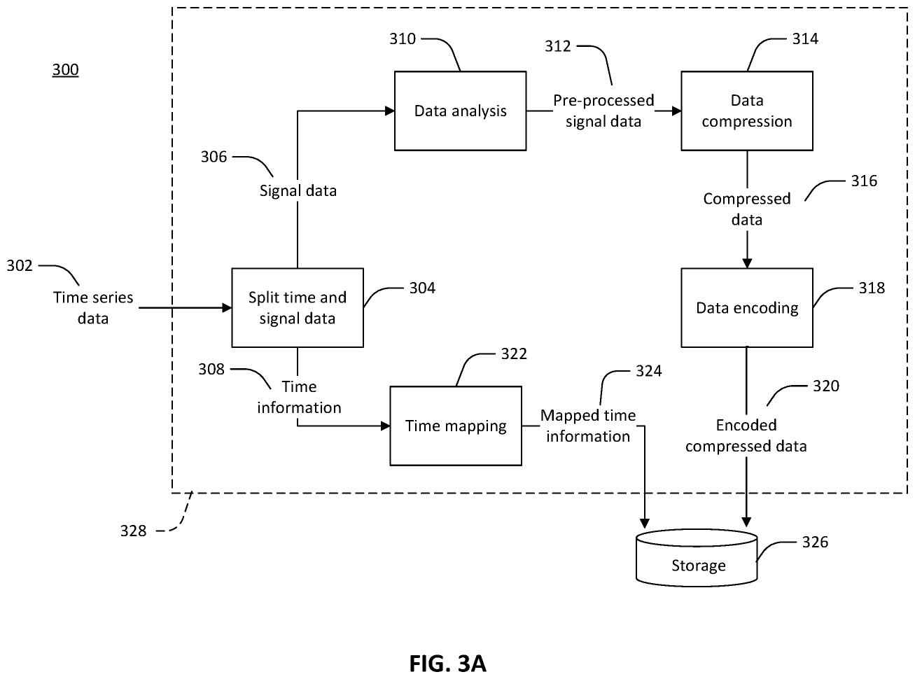

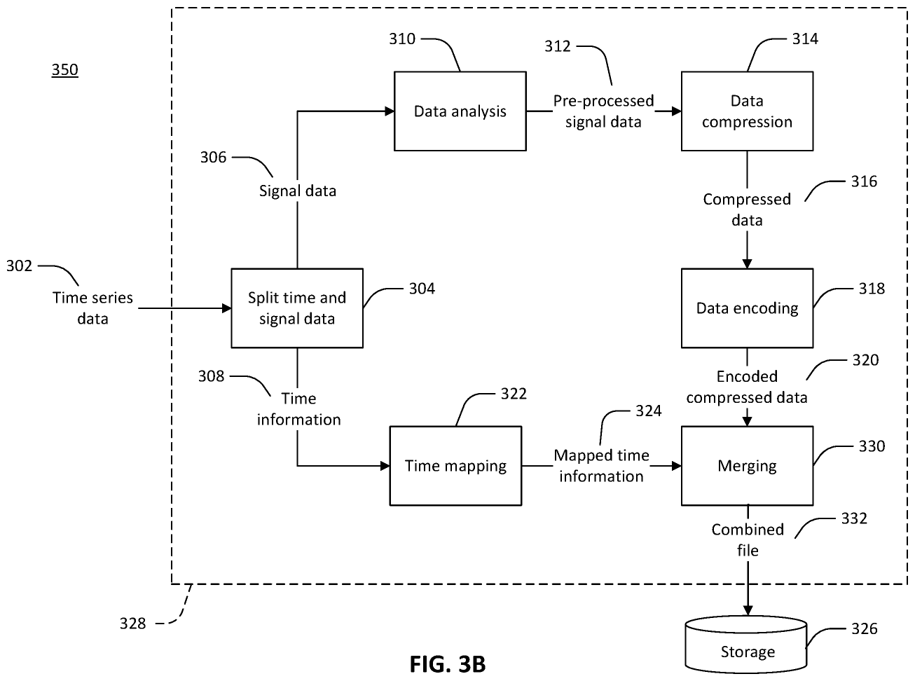

A write path as used herein is a process for creating compressed data and an index into the compressed data from raw time series data. FIG. 3A is a flow diagram showing an information flow 300 for creating compressed data from raw time series data and an index into the compressed data, consistent with some embodiments of the present disclosure.

Time series data 302 may be provided to a splitting component 304. The splitting component 304 may be configured to split the time series data 302 into signal data 306 and time information 308. For example, for storage system monitoring data, the data is sent in pairs (timestamp, data point) and the splitting component 304 extracts the timestamps from the received data pairs. The signal data 306 and the time information 308 may be separately processed.

The signal data 306 may be forwarded to a data analysis component 310. The data analysis component 310 may be configured to analyze the signal data 306 to determine a type of data contained in the signal data 306. For example, the signal data 306 may include integer data and floating point data. In some embodiments, the data analysis component 310 may be configured to divide the signal data 306 into segments for later processing. For example, it may be computationally simpler and/or more efficient to divide the signal data 306 into smaller segments for processing. In some embodiments, the signal data 306 may be divided into similarly-sized or equal-sized segments. For example, each segment may include 2^{N} data samples, with N being an integer. In some instances, it may be computationally simpler or computationally efficient to process a segment including 2^{N} samples. The data analysis component 310 may be configured to output pre-processed signal data 312 to a data compression component 314.

In some embodiments, the signal data 306 may be divided into segments using wavelets. Wavelets may be effective in identifying instances of change in the data (e.g., by creating a spike when there is a transition on the original data). When the transition is located, the data may be segmented. This transition may be easy to notice (in graphical form) because a spike exists on all frequencies and the spike is likely a data point. It is noted the using wavelets may be more computationally expensive than dividing the signal data 306 into 2^{N} data samples.

The data compression component 314 may be configured to compress the pre-processed signal data 312 based on information included with the pre-processed signal data 312, such as the data type. Different compression algorithms may be applied depending on the data type. For example, integer data may be compressed using a delta compression algorithm, while floating point data may be compressed using a logical exclusive OR (XOR) algorithm. Other compression algorithms may also be applied, such as Fast Fourier Transform (FFT) or polynomial approximations (e.g., Hermite Splines). Other data types may be identified by the data analysis component 310 and compressed by the data compression component 314 using a compression algorithm corresponding to the identified data type. The data compression component 314 may be configured to output compressed data 316 to a data encoding component 318.

In some embodiments, the data compression component 314 may be configured to select a compression algorithm from one of a subset of possible compression algorithms. Because different data segments may have different characteristics, some data segments may be able to be compressed to a greater extent (i.e., resulting in a smaller compressed file) by selecting a compression algorithm more suited to the data. As a result, different segments of the data may be compressed using different algorithms.

In some embodiments, a higher number of data samples (i.e., a higher volume of data) may permit a higher compression ratio to be achieved. For example, the same mathematical formula may be used, regardless of the number of data samples. So even as the number of input data samples grows, the output the compression algorithm stays mostly the same. For example, if a line equation is used (e.g., y=mx+b), the same equation may be used whether there are 10 data samples or 10 million data samples. In some embodiments, a more lossy compression algorithm may be used, depending on the type of data being stored. For example, for storage system monitoring data, for CPU usage metrics, the most common usage is for determining CPU usage trends, so every single data sample does not need to be stored or recoverable (and as such, a more lossy compression algorithm may be used).

Some embodiments may include a machine learning (ML) model that is trained on historic data and then used to select the compression method. For example, the machine learning model may include a supervised model, an unsupervised model, a reinforcement learning model, and other suitable models. In some embodiments, the trained ML model may be implemented in the data compression component 314.

The data encoding component 318 may be configured to encode the compressed data 316 into a file format for storage. In some embodiments, the compressed data 316 may be stored as a mathematical formula used to compress the data by the data compression component 314. For example, the mathematical formula may be stored as a text file or other file type suitable for storing mathematical formulas. The data encoding component 318 may be configured to output encoded compressed data 320 to a storage 326.

The time information 308 may be provided to a time mapping component 322. The time mapping component 322 may be configured to generate an index that may be used to access the data samples of the signal data 306 with precision, which provides the ability to retrieve certain data samples of the signal data 306 without having to obtain all the signal data 306 and perform a full file seek operation. For example, the time mapping component 322 may be configured to store a timestamp indicating a start of a time period, a timestamp indicating an end of the time period, and a sample interval indicating how frequently the data samples were taken during the time period (i.e., how frequently the data was sampled). For example, the start of the time period may be 00:00:00 (i.e., midnight), the end of the time period may be 23:59:40, and the interval may be 20 seconds. This information may be stored as a line or other data structure. The time mapping component 322 may be configured to output mapped time information 324 to the storage 326.

The encoded compressed data 320 and the mapped time information 324 occupy less storage space, require fewer processing resources, and require less network bandwidth for transmission than the original time series data 302. In some embodiments, the encoded compressed data 320 and the mapped time information 324 may be stored as separate files in the storage 326. The separate files may be associated together such that the correct index is associated with the signal data it was separated from. For example, the files may have similar file names or may be associated in another suitable manner.

In some embodiments, the splitting component 304, the data analysis component 310, the data compression component 314, the data encoding component 318, and the time mapping component 322 may all be subcomponents of a streaming compressor 328 (shown in FIG. 3A by a dashed outline). In some embodiments, the streaming compressor 328 may be implemented as hardware, software, or a combination of hardware and software. For example, the hardware may include a CPU, a GPU, an ASIC, a FPGA, or other circuitry configured to perform the operations of information flow 300.

In some embodiments, using the streaming compressor 328 may lead to higher compression ratios. For example, one month of time series data may be compressed, and then new data may be added every day or every hour. The more data that is added, the higher the compression ratios that may be achieved, because more similarities among the data may be determined.

FIG. 3B is a flow diagram showing an alternate information flow 350 for creating compressed data and an index from raw time series data, consistent with some embodiments of the present disclosure. The information flow 350 operates in a similar manner as the information flow 300 described in connection with FIG. 3A. Components common to flows 300 and 350 have the same reference numbers and the same functions as described above and the descriptions of those common components are not repeated.

The information flow 350 may include a merging component 330 configured to combine the encoded compressed data 320 and the mapped time information 324 to form a combined file 332. The combined file 332 may be stored in storage 326. In some embodiments, the merging component 330 may be part of the streaming compressor 328. In some embodiments, the merging component 330 may be separate from the streaming compressor 328 and may be externally located in the flow between the streaming compressor 328 and the storage 326.

In some embodiments, when new data is added, if the new data looks like previously stored data, the new data may not need to be compressed again and may just be pointed to. For example, if the statistical analysis (e.g., by data analysis component 310) determines that the new data is the same data as before, then the new data does not need to be compressed and a count of the data samples stored in the existing compression formula may be increased. As another example, the new data may be combined with the previously stored data and may be compressed. If the compression output is the same as the previous compression output, then the new compression may be discarded and the data sample count of the previous compression output may be increased.

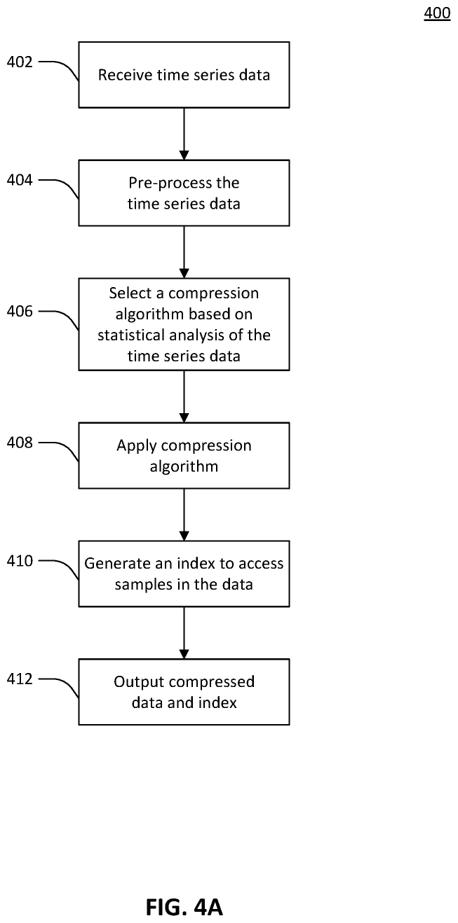

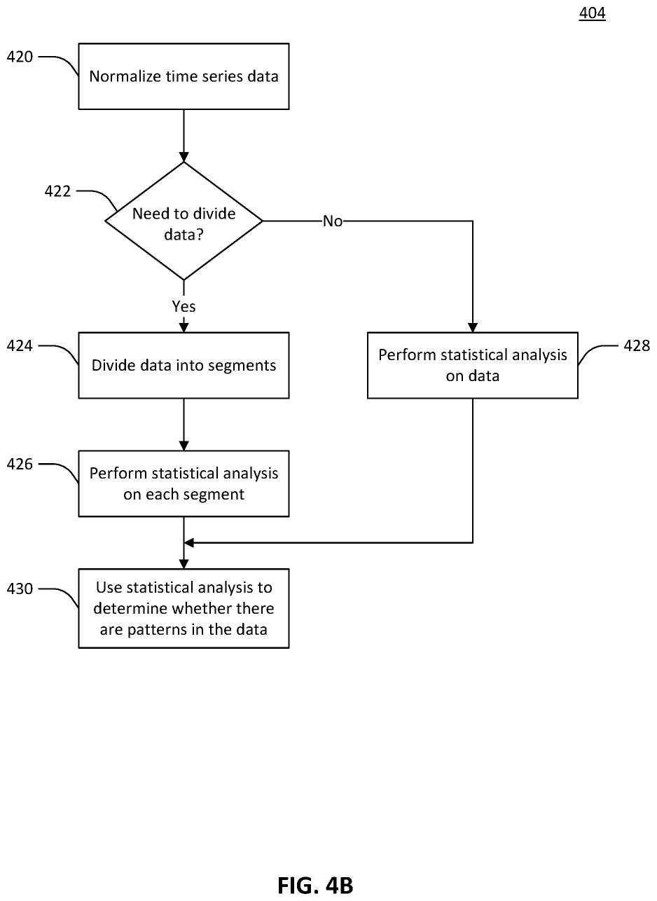

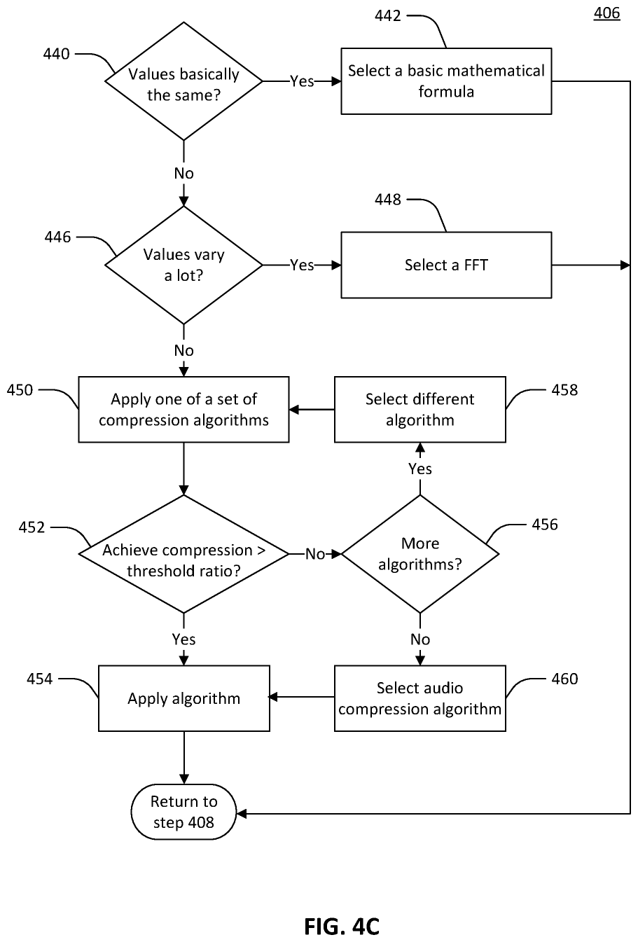

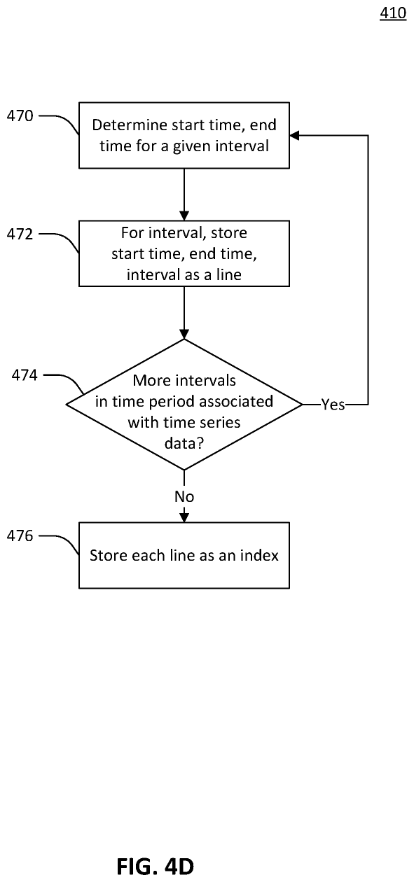

FIGS. 4A-4D illustrate a flowchart of an exemplary method 400 for creating compressed data and an index from time series data, consistent with some embodiments of the present disclosure. For purposes of explanation, FIG. 4A illustrates the entire overall method 400 and FIGS. 4B-4D illustrate details of certain steps of the method 400 shown in FIG. 4A.

The time series data may be received at a processing component (step 402). For example, the processing component may include the streaming compressor 328 shown in FIGS. 3A and 3B.

The time series data may be pre-processed to determine a type of data in the time series data, such as whether the data includes integer data or floating point data (step 404). The pre-processing may also include splitting the time series data into signal data and time information (e.g., similar to splitting component 304 shown in FIGS. 3A and 3B) and may include dividing the signal data into segments for further processing.

Referring to FIG. 4B, pre-processing the time series data (step 404) may include several sub-steps. The time series data may be normalized (step 420). For example, the time series data may be scaled to be in a range from 0 to 1. Other ranges or normalization procedures are possible without modifying the overall operation of step 404.

After the data is normalized, a determination is made whether the data needs to be divided (step 422). For example, it may be computationally easier to use smaller segments of data for further processing. The determination whether to divide the data may be based on, for example, a total number of data samples (or data points) in the time series data.

If the data needs to be divided (step 422, “yes” branch), then the data may be divided into segments (step 424). In some embodiments, the data may be divided into segments of 2^{N} samples per segment, where N is an integer. In some embodiments, the data may be divided into segments using wavelets, as described above in connection with FIGS. 3A and 3B. A statistical analysis is performed on each data segment (step 426). If the data is not divided (step 422, “no” branch), then a statistical analysis is performed on the data (step 428). The statistical analysis (either step 426 or step 428) is used to determine whether there are patterns in the data (step 430).

Referring back to FIG. 4A, a compression algorithm best suited to compress the data is selected based on the statistical analysis that was performed on the pre-processed data (step 406). For example, the statistical analysis may be performed by the data analysis component 310 or the data compression component 314 shown in FIGS. 3A and 3B.

Referring to FIG. 4C, selecting the compression algorithm (step 406) may include several sub-steps. First, a determination may be made whether the data values are basically the same (step 440). For example, if the data represents a constant value, all the data elements would be the same. Similarly, if the minimum value in the data and the maximum value in the data are close to each other, then the data may indicate a near-constant value. If the data values are basically the same (step 440, “yes” branch), then a basic mathematical formula, such as a line, may be selected (step 442) and the method returns to step 408 (as shown in FIG. 4A). For example, if the data values are constant or near-constant, then the data may be represented as a line. For example, a line may be represented by a tuple indicating a start value, an end value, and an interval value or may be represented as a formula, such as y=mx+b.

If the data values are not basically the same (step 440, “no” branch), then a determination may be made whether the data values vary a lot (step 446). For example, the data values may frequently cross the zero line. If the data values vary a lot (step 446, “yes” branch), then a Fast Fourier Transform (FFT) may be selected (step 448) because a signal that often cross the zero line may be a good candidate for using the FFT and the method returns to step 408 (as shown in FIG. 4A).

If the data values do not vary a lot (step 446, “no” branch), then the data may be considered to be “noisy data” and an iterative process may be performed in which various candidate compression algorithms are applied to the data values to determine which candidate compression algorithm achieves the best compression. As used herein, the term “best compression” may indicate that a candidate compression algorithm achieves a compression ratio greater than a predetermined threshold (e.g., greater than 90%). A candidate compression algorithm is selected and applied to the data values (step 450). A determination is made whether applying the selected candidate compression algorithm achieves a compression ratio greater than a threshold compression ratio (step 452). In some embodiments, the threshold compression ratio may be a fixed value, may be a user determined value (e.g., an adjustable parameter), or may be selected based on the data type (e.g., integer or floating point). If the compression ratio achieved is greater than the threshold compression ratio (step 452, “yes” branch), then the selected candidate algorithm is applied (step 454) and the method returns to step 408 (as shown in FIG. 4A).

If the compression ratio achieved is not greater than the threshold compression ratio (step 452, “no” branch), then a determination is made whether there are additional candidate compression algorithms to be applied (step 456). In some embodiments, a predetermined “library” of candidate compression algorithms may be selected from. For example, the “library” may include several different compression algorithms, such as a line, an FFT, a polynomial (e.g., a polynomial from the Cubic Hermite spline family, an inverse distance weight polynomial, or a Catmull-Rom spline polynomial), or a type compressor. In some embodiments, the type compressor may be used to minimize the data values to the smallest binary format that fits the data. The data values may not be changed, just the data format for the data values. For example, if the original format for the time series data is Float64 (which uses a large amount of storage space per data element), the data values may be analyzed to determine whether a small integer may be used instead. In such circumstances, the data values could be converted from the Float64 format to an integer format, thereby saving storage space.

If there are additional candidate compression algorithms to be applied (step 456, “yes” branch), then a different candidate algorithm is selected (step 458) and is applied (step 450) as described above. If there are no additional candidate compression algorithms to be applied (step 456, “no” branch), then an audio compression algorithm is selected (step 460) and is applied (step 454). The method then returns to step 408 (as shown in FIG. 4A).

In step 460, an audio compression algorithm such as WAV or FLAC may be used. In some embodiments where an audio compression algorithm is used, various audio packaging, encoding, and compression techniques may be applied to the data values.

Some embodiments of the audio compression algorithm may divide the data into different channels, such as a left channel, a right channel, a center channel, and a rear channel similar to the format of a multi-channel audio signal. For example, because audio processing algorithms have been optimized to operate on 16-bit channels, 64-bit monitoring data may be broken into four 16-bit channels. For example, data may be configured as stereo signals (e.g., a left channel and a right channel), which are highly correlated signals, such that all the data do not need to be stored for both channels. If the data is correlated, one channel may be retained and the difference for the other channel may be stored, leading to a higher compression ratio and requiring less storage space. Based on the data, correlated signals may be selected in pairs and “pushed” into a stereo channel format. For example, if the signals show the same mathematical formula approximation (e.g., y=mx+b), then the signal may be normalized (e.g., subtract the average of both signals). Then, a correlation mathematical approach may be used to verify and proceed (e.g., Dynamic Time Warping). As an example, in some embodiments, a disk usage metric, which does not change much over time, may be placed into a center channel (which usually does not contain a large amount of information) to further reduce the storage requirements.

The transformation from the data values into an audio file format may take into account properties of the data values (e.g., frequency) to optimize how the data values can be encoded and compressed. For example, audio compressors may perform better with high frequencies, so the frequency of the data may be “faked” (i.e., artificially increased) to take advantage of these benefits. Audio signals typically have a frequency range between 8 kHz and 300 kHz, while some time series data, such as storage system monitoring data, has a substantially lower frequency. For example, one day of storage system monitoring data may be about the same amount of data as one second of audio.

As an optimization, certain types of data may be selectively stored in channels that are processed using encoding and compression techniques best suited for such types of data. For example, for storage system monitoring data, CPU utilization may vary greatly over short periods of time, which may be suitable for a left channel or right channel that is processed using techniques tailored for higher frequencies or samples of audio data. As another example for storage system monitoring data, storage utilization may vary slowly over time, which may be suitable for a center channel that is processed using techniques tailored for lower frequencies or samples of audio data.

It is noted that the sub-steps of step 406 described above illustrate one exemplary implementation of selecting a compression algorithm and that other implementations of selecting a compression algorithm are possible.

Referring back to FIG. 4A, the selected compression algorithm is applied to the time series data (step 408).

An index to access the samples in the compressed data may be generated (step 410). For example, the index may be generated from time information removed from the time series data (e.g., similar to splitting component 304 shown in FIGS. 3A and 3B) and processed separately from the compressed data (e.g., similar to time mapping component 322 shown in FIGS. 3A and 3B).

Referring to FIG. 4D, generating the index (step 410) may include several sub-steps. The index may be generated from the time information split from the time series data (e.g., by splitting component 304 shown in FIGS. 3A and 3B). A start time and an end time for a given data sampling interval are determined (step 470). For example, data may be collected on an interval of every 20 seconds from 00:00:00 (i.e., midnight) to 23:59:40 of the same day. The start time, the end time, and the interval may be stored as a line (step 472). In some embodiments, the start time, the end time, and the interval may be stored as a tuple.

A determination is made whether there are more intervals in the time period associated with the time series data (step 474). For example, during a day, the time series data may be stored at different intervals. For example, from 00:00:00 to 08:00:00, the data may be sampled every 20 seconds; from 08:00:00 to 18:00:00, the data may be sampled every 10 seconds; and from 18:00:00 to 23:59:59, the data may be sampled every 20 seconds. In this example, there are three separate time periods involved and a separate line will be generated for each separate time period (i.e., each sampling interval has a separate line/index). If there are more intervals in the time period (step 474, “yes” branch), then the method returns to step 470 to determine the start time and the end time for the interval. Continuing the above example, one line is generated for the 20 second interval between 00:00:00 to 08:00:00, a second line is generated for the 10 second interval between 08:00:00 to 18:00:00, and a third line is generated for the 20 second interval between 18:00:00 to 23:59:59. Similarly, if there is a period of time for which there is no data (e.g., from 17:00:00 to 18:00:00 there is no data, but there is data from 00:00:00 to 17:00:00 and from 18:00:00 to 23:59:59), then the information for the period of time with no data would be stored as a separate line. In this example, there would be three separate lines, a first line for 00:00:00 to 17:00:00, a second line for 17:00:00 to 18:00:00, and a third line for 18:00:00 to 23:59:59.

If there are no more intervals in the time period (step 474, “no” branch); i.e., all lines covering the time period have been generated, then each line is stored as an index (step 476). For example, the multiple lines may be stored in a text file or other file format. Because each line includes information relating to the start time and the end time, multiple lines may be stored together in a single file.

Referring back to FIG. 4A, the compressed data and the index may be output (step 412). In some embodiments, the compressed data and the index may be stored (e.g., in storage 326 shown in FIG. 3) or transmitted.

### Exemplary Read Path

A read path as used herein is a process for locating specific data within the compressed time series data. Because timestamp information is not stored with the time series data in some embodiments, the indexing technique (as described elsewhere in this disclosure) may be used to quickly locate relevant portions of the compressed time series data file (i.e., portions containing the specific data) to be streamed to a customer. The indexing technique also enables only the relevant portions of the file to be transmitted and decompressed and irrelevant portions of the file (i.e., portions of the file that do not include the specific data) are not transmitted or decompressed.

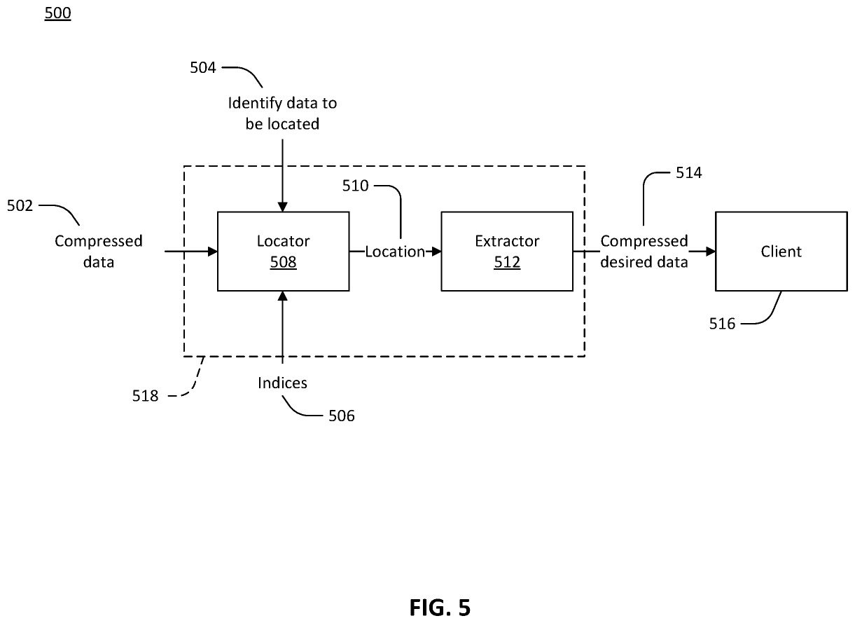

FIG. 5 is a flow diagram showing an information flow 500 for locating particular data in compressed time series data, consistent with some embodiments of the present disclosure. Compressed time series data 502 (e.g., compressed data 320 as shown in FIGS. 3A and 3B), information 504 identifying data to be located, and indices 506 (e.g., mapped time information 324 as shown in FIGS. 3A and 3B) may be provided to a locator component 508. For example, the information 504 may include information to be queried, such as CPU storage metrics for a particular timespan in compressed time series data containing storage system monitoring data. For example, the information 504 may be provided via a user interface or an application programming interface.

A locator component 508 may be configured to use the information 504 to access the index 506 to locate the desired data in the compressed data 502. For example, if a user wants to retrieve data relating to CPU storage metrics at 18:00:00 on Jan. 5, 2024, the compressed data 502 may include a data file of CPU storage metrics for Jan. 5, 2024, the information 504 may include the desired timestamp (e.g., 18:00:00), and the indices 506 may include one or more indices for the CPU storage metrics for Jan. 5, 2024.

The locator component 508 may be configured to provide a location 510 in the compressed data 502 where the desired data is located to an extractor component 512. Continuing the above example, if there are three indices, a first index covering 00:00:00 to 17:00:00, a second index covering 17:00:00 to 19:00:00, and a third index covering 19:00:00 to 23:59:59, the second index may be used to find a location in the compressed data 502 corresponding to data for the desired timestamp of 18:00:00.

The extractor component 512 may be configured to use the location 510 to extract the desired data from the compressed data 502. Continuing the above example, it may be relatively simple to determine the location of the data containing the CPU storage metrics associated with the timestamp 18:00:00. For example, because the start time (e.g., 17:00:00) and the end time (e.g., 19:00:00) for the index and the interval (e.g., 10 seconds) are known, a number corresponding to a position of the CPU storage metrics for 18:00:00 may be calculated. The extractor 512 may be configured to output the compressed desired data 514 to a client 516. The client 516 may include, for example, a Web browser running on a computing device (e.g., a laptop, a desktop, a tablet, a mobile device, or other computing device configured to display data to a customer). By providing the compressed desired data 514 to the client 516, transmission bandwidth may be less than transmitting the uncompressed data or than transmitting more data than is needed to satisfy the user's query.

In some embodiments, the locator component 508 and the extractor component 512 may be subcomponents of a streaming decompressor 518 (shown in FIG. 5 by a dashed outline). In some embodiments, the streaming decompressor 518 may be implemented as hardware, software, or a combination of hardware and software. For example, the hardware may include a CPU, a GPU, an ASIC, a FPGA, or other circuitry configured to perform the operations of information flow 500.

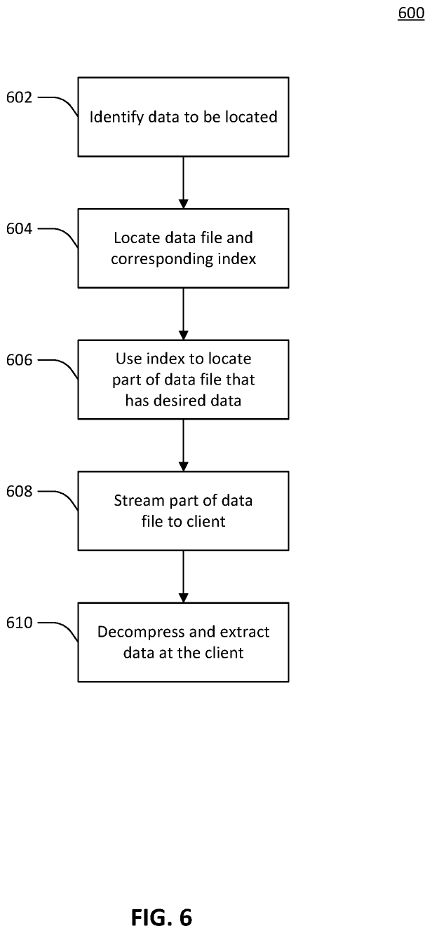

FIG. 6 is a flowchart of an exemplary method 600 for locating particular data in compressed time series data, consistent with some embodiments of the present disclosure. Information identifying the data to be located, the compressed time series data, and one or more indices may be received at a processing component (step 602). For example, the processing component may include the streaming decompressor 518 shown in FIG. 5.

The data file and the corresponding index into the data file may be located in a storage (step 604), e.g., storage 326 as shown in FIG. 3. The index may be used to locate a part of the data file that includes the desired data (step 606), e.g., similar to locator component 508 shown in FIG. 5.

Relevant data from the data file may be extracted from the compressed time series data and streamed to a client (step 608), e.g., similar to extractor component 512 shown in FIG. 5.

At the client side, the data may be decompressed and the desired information may be extracted from the decompressed data using information from the index (step 610). In some embodiments, the compressed data received by the client may include the mathematical formula used to compress the data. In some embodiments, the compressed data received by the client may include a tag that identifies the mathematical formula used to compress the data.

### Server

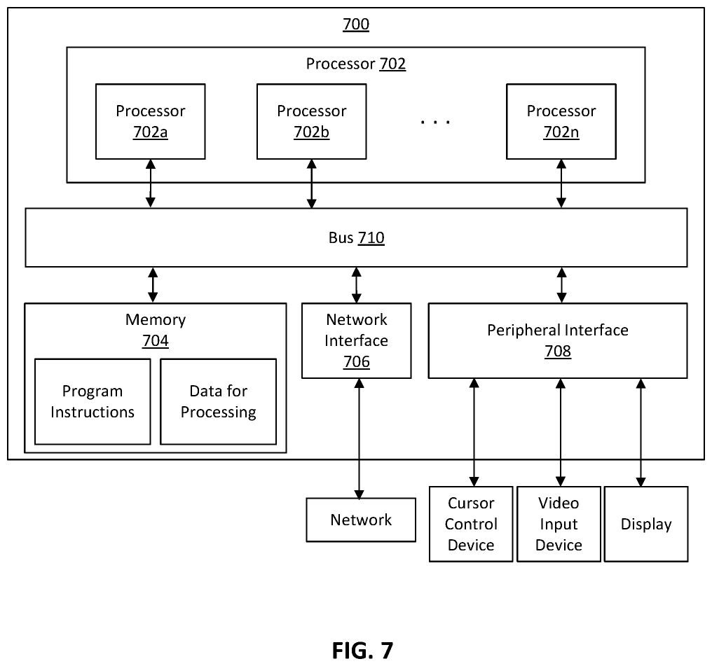

FIG. 7 is a block diagram of an exemplary server 700 that may be used to perform the functions of the system 200 shown in FIG. 2, consistent with some embodiments of the present disclosure.

As shown in FIG. 7, the server 700 can include a processor 702, which can be any type of circuitry capable of manipulating or processing information. For example, the processor 702 can include any combination of any number of a central processing unit (“CPU”), a graphics processing unit (“GPU”), a programmable logic controller, a microcontroller, a microprocessor, a digital signal processor, an intellectual property (IP) core, a Complex Programmable Logic Device (CPLD), a Field-Programmable Gate Array (FPGA), a System On Chip (SoC), an Application-Specific Integrated Circuit (ASIC), or the like. In some embodiments, the processor 702 can also be a set of processors grouped as a single logical component. For example, as shown in FIG. 7, the processor 702 can include multiple processors, including a processor 702a, a processor 702b, and a processor 702n.

The server 700 can also include a memory 704 configured to store data (e.g., a set of instructions, computer codes, intermediate data, or the like). For example, as shown in FIG. 7, the stored data can include program instructions and data for processing. the processor 702 can access the program instructions and data for processing (e.g., via a bus 710), and execute the program instructions to perform an operation on the data for processing. The memory 704 can include a high-speed random-access storage device or a non-volatile storage device. In some embodiments, the memory 704 can include any combination of any number of a random-access memory (RAM), a read-only memory (ROM), an optical disc, a magnetic disk, a hard drive, a solid-state drive, a flash drive, a secure digital (SD) card, a memory stick, a compact flash (CF) card, or the like. The memory 704 can also be a group of memories (not shown in FIG. 7) grouped as a single logical component.

The bus 710 can be a communication device that transfers data between components within the server 700, such as an internal bus (e.g., a CPU-memory bus), an external bus (e.g., a universal serial bus port, a peripheral component interconnect express port), or the like.

For ease of explanation, the processor 702 and other data processing circuits are collectively referred to as a “data processing circuit” in this disclosure. The data processing circuit can be implemented entirely as hardware, or as a combination of software, hardware, or firmware. In addition, the data processing circuit can be a single independent module or can be combined entirely or partially into any other component of the server 700.

The server 700 can further include a network interface 706 to provide wired or wireless communication with a network (e.g., the Internet, an intranet, a local area network, a mobile communications network, or the like). In some embodiments, the network interface 706 can include any combination of any number of a network interface controller (NIC), a radio frequency (RF) module, a transponder, a transceiver, a modem, a router, a gateway, a wired network adapter, a wireless network adapter, a near-field communication (“NFC”) adapter, a cellular network chip, or the like.

In some embodiments, optionally, the server 700 can further include a peripheral interface 708 to provide a connection to one or more peripheral devices. As shown in FIG. 7, the peripheral devices can include, but are not limited to, a cursor control device (e.g., a mouse, a touchpad, or a touchscreen), a keyboard, a display (e.g., a liquid crystal display or a light-emitting diode display), a video input device (e.g., a camera), or the like.

The present disclosure, in connection with the accompanied drawings, describes example configurations that are not representative of all the examples that may be implemented or all configurations that are within the scope of this disclosure. Instead, they are merely examples of systems, apparatuses, and methods consistent with aspects related to the present disclosure as recited in the appended claims. The term “exemplary” should not be construed as “preferred” or “advantageous compared to other examples” but rather “an illustration, an instance or an example.” By reading this disclosure, including the description of the embodiments and the drawings, it will be appreciated by a person of ordinary skills in the art that the technology disclosed herein may be implemented using alternative embodiments. The person of ordinary skill in the art would appreciate that the embodiments, or certain features of the embodiments described herein, may be combined to arrive at yet other embodiments for practicing the technology described in the present disclosure. Thus, the disclosure is not limited to the examples and designs described herein but is to be accorded the broadest scope consistent with the principles and novel features disclosed herein.

The flowcharts and block diagrams in the figures illustrate examples of the architecture, functionality, and operation of possible implementations of systems, methods, and devices according to various embodiments. It should be noted that, in some alternative implementations, the functions noted in blocks may occur out of the order noted in the figures. For example, two blocks shown in succession may, in fact, be executed substantially concurrently, or the blocks may sometimes be executed in the reverse order, depending upon the functionality involved. Likewise, additional steps may be included in such methods, and certain steps may be omitted or combined, in methods consistent with various embodiments.

It is understood that the described embodiments are not mutually exclusive, and elements, components, materials, or steps described in connection with one example embodiment may be combined with, or eliminated from, other embodiments in suitable ways to accomplish desired design objectives.

Reference herein to “some embodiments” or “some exemplary embodiments” means that a particular feature, structure, or characteristic described in connection with the embodiment can be included in at least one embodiment. The appearance of the phrases “one embodiment” “some embodiments” or “another embodiment” in various places in the present disclosure do not all necessarily refer to the same embodiment, nor are separate or alternative embodiments necessarily mutually exclusive of other embodiments.

Additionally, the articles “a” and “an” as used in the present disclosure and the appended claims should generally be construed to mean “one or more” unless specified otherwise or clear from context to be directed to a singular form.

It will be further understood that various modifications, alternatives, and variations in the details, materials, and arrangements of the parts which have been described and illustrated to explain the nature of described embodiments may be made by those skilled in the art without departing from the scope. Accordingly, the following claims embrace all such alternatives, modifications, and variations that fall within the terms of the claims.

What is claimed is:

1. A method for processing storage system monitoring data, comprising:
splitting received storage system monitoring data into signal data and time information;
pre-processing the signal data to perform a statistical analysis on the signal data;
selecting a compression algorithm based on the statistical analysis on the signal data;
compressing the signal data using the selected compression algorithm;
generating an index from the time information to access samples in the compressed data; and
outputting the compressed data and the index.

2. The method of claim 1, wherein the storage system monitoring data includes one or more of: central processing unit (CPU) usage, CPU utilization, memory usage, storage utilization, database latency, and disk latency.

3. The method of claim 1, wherein pre-processing the signal data includes normalizing the signal data.

4. The method of claim 1, wherein:
pre-processing the signal data includes:
dividing the signal data into segments; and
performing the statistical analysis on each of the segments; and
selecting the compression algorithm includes selecting a compression algorithm for each segment based on the statistical analysis for each segment.

5. The method of claim 1, wherein:
pre-processing the signal data includes:
dividing the signal data into segments, wherein each of the segments includes 2^{N} samples, where N is an integer; and
performing the statistical analysis on each of the segments;
selecting the compression algorithm includes selecting a compression algorithm for each segment based on the statistical analysis for each segment; and
compressing the signal data includes compressing the signal data of each segment using the selected compression algorithm for each segment.

6. The method of claim 1, wherein on a condition that the statistical analysis indicates that data values in the signal data are similar, selecting the compression algorithm includes selecting a basic mathematical formula.

7. The method of claim 1, wherein on a condition that the statistical analysis indicates that data values in the signal data cross a zero line multiple times, selecting the compression algorithm includes selecting a Fast Fourier Transform.

8. The method of claim 1, wherein on a condition that the statistical analysis indicates that data values in the signal data are noisy, selecting the compression algorithm includes:
selecting a candidate compression algorithm from a predetermined library of candidate compression algorithms;
applying the selected candidate compression algorithm to determine whether the selected candidate compression algorithm achieves a threshold compression ratio;
on a condition that the selected candidate compression algorithm achieves a threshold compression ratio, selecting the candidate compression algorithm as the compression algorithm;
on a condition that the selected candidate compression algorithm does not achieve the threshold compression ratio, selecting a different candidate compression algorithm from the predetermined library; and
on a condition that all candidate compression algorithms in the predetermined library have been applied, selecting the compression algorithm includes selecting an audio compression algorithm.

9. The method of claim 1, wherein generating the index includes:
determining a start time and an end time for a given sampling interval; and
storing the start time, the end time, and the interval as a line.

10. A system for processing storage system monitoring data, comprising:
a memory configured to store instructions; and
a processor configured to execute the instructions stored in the memory to:
split received storage system monitoring data into signal data and time information;
pre-process the signal data to perform a statistical analysis on the signal data;
select a compression algorithm based on the statistical analysis on the signal data;
compress the signal data using the selected compression algorithm;
generate an index from the time information to access samples in the compressed data by:
determining a start time and an end time for a given sampling interval; and
storing the start time, the end time, and the interval as a line; and
output the compressed data and the index.

11. The system of claim 10, wherein the processor is further configured to pre-process the signal data by normalizing the signal data.

12. The system of claim 10, wherein the processor is further configured to:
pre-process the signal data by:
dividing the signal data into segments, wherein each segment includes 2^{N} samples, where N is an integer; and
performing the statistical analysis on each segment;
select the compression algorithm by selecting a compression algorithm for each segment based on the statistical analysis for each segment; and
compress the signal data by compressing the signal data of each segment using the selected compression algorithm for each segment.

13. The system of claim 10, wherein on a condition that the statistical analysis indicates that data values in the signal data are similar, the processor is further configured to select the compression algorithm by selecting a basic mathematical formula.

14. The system of claim 10, wherein on a condition that the statistical analysis indicates that data values in the signal data cross a zero line multiple times, the processor is further configured to select the compression algorithm by selecting a Fast Fourier Transform.

15. The system of claim 10, wherein on a condition that the statistical analysis indicates that data values in the signal data are noisy, the processor is further configured to select the compression algorithm by:
selecting a candidate compression algorithm from a predetermined library of candidate compression algorithms;
applying the selected candidate compression algorithm to determine whether the selected candidate compression algorithm achieves a threshold compression ratio;
on a condition that the selected candidate compression algorithm achieves a threshold compression ratio, selecting the candidate compression algorithm as the compression algorithm;
on a condition that the selected candidate compression algorithm does not achieve the threshold compression ratio, selecting a different candidate compression algorithm from the predetermined library; and
on a condition that all candidate compression algorithms in the predetermined library have been applied, selecting the compression algorithm includes selecting an audio compression algorithm.

16. A non-transitory machine-readable medium containing instructions that, when executed by a machine, cause the machine to:
split received storage system monitoring data into signal data and time information;
pre-process the signal data to perform a statistical analysis on the signal data by:
dividing the signal data into segments, wherein each of the segments includes 2^{N} samples, where N is an integer; and
performing the statistical analysis on each of the segments;
select a compression algorithm for each segment based on the statistical analysis for the segment;
compress the signal data of each segment using the selected compression algorithm for each segment;
generate an index from the time information to access samples in the compressed data; and
output the compressed data and the index.

17. The non-transitory machine-readable medium of claim 16, wherein the instructions further cause the machine to generate the index by:
determining a start time and an end time for a given sampling interval; and
storing the start time, the end time, and the interval as a line.

18. The non-transitory machine-readable medium of claim 16, wherein on a condition that the statistical analysis indicates that data values in the signal data are similar, the instructions further cause the machine to select the compression algorithm by selecting a basic mathematical formula.

19. The non-transitory machine-readable medium of claim 16, wherein on a condition that the statistical analysis indicates that data values in the signal data cross a zero line multiple times, selecting the compression algorithm includes selecting a Fast Fourier Transform.

20. The non-transitory machine-readable medium of claim 16, wherein on a condition that the statistical analysis indicates that data values in the signal data are noisy, the instructions further cause the machine to select the compression algorithm by:
selecting a candidate compression algorithm from a predetermined library of candidate compression algorithms;
applying the selected candidate compression algorithm to determine whether the selected candidate compression algorithm achieves a threshold compression ratio;
on a condition that the selected candidate compression algorithm achieves a threshold compression ratio, selecting the candidate compression algorithm as the compression algorithm;
on a condition that the selected candidate compression algorithm does not achieve the threshold compression ratio, selecting a different candidate compression algorithm from the predetermined library; and
on a condition that all candidate compression algorithms in the predetermined library have been applied, selecting the compression algorithm includes selecting an audio compression algorithm.
